(19) United States
(12) Patent Application Publication
(10) Pub. No.: US 2015/0179839 A1
(43) Pub. Date: Jun. 25, 2015

(54) CONTACT LAYERS FOR PHOTOVOLTAIC DEVICES

(71) Applicant: Intermolecular Inc., San Jose, CA (US)

(72) Inventors: Jeroen Van Duren, Palo Alto, CA (US); Khaled Ahmed, Anaheim, CA (US); Haifan Liang, Fremont, CA (US)

(73) Assignee: Intermolecular Inc., San Jose, CA (US)

(21) Appl. No.: 14/138,555

(22) Filed: Dec. 23, 2013

(51) Int. Cl. H01L 31/0224; H01L 31/18

(52) U.S. Cl. CPC H01L 31/022441; H01L 31/18

(57) ABSTRACT

Solar cells and methods for forming a back contact layer for a solar cell are disclosed. The methods comprise depositing a first layer comprising a conductor on a substrate, depositing a second layer on the first layer, the second layer comprising between about 1 nm and about 25 nm of a metal chalcogenide, and forming a third layer operable as an absorber layer on the second layer. The absorber layer can comprise a photoactive semiconductor layer. In some embodiments, the absorber layer comprises a chalcogenide of copper-indium-gallium. In some embodiments, the absorber layer comprises a chalcogenide of copper-zinc-tin. In some embodiments, the absorber layer comprises CdTe. In some embodiments, the metal comprises Mo, W or Ta. In some embodiments, the metal comprises Mo. In some embodiments, the chalcogenide comprises S or Se or a combination thereof.

### CROSS-REFERENCE TO RELATED APPLICATION

This application is related to U.S. patent application Ser. No. 13/251,509, filed on Oct. 3, 2011, and U.S. patent application Ser. No. 13/283,291, filed on Oct. 27, 2011, each of which is herein incorporated by reference for all purposes.

### FIELD OF THE INVENTION

One or more embodiments of the present invention relate to contact layers for photovoltaic devices and methods of making thereof.

### BACKGROUND

The back-contact for thin-film photovoltaic (PV) devices (solar cells) needs to fulfill various requirements: conductivity to carry the current, (quasi-)ohmic contact to the absorber, (quasi-)ohmic contact to the transparent conductive oxide (TCO) layer at the series-connect (monolithic integration), good adhesion to tabs, ease of scribing, thermo-mechanical stability during manufacturing and as a product in the field, chemical resistance (especially to Ga, Se, and H₂O), ability to function as a diffusion barrier, and optical reflectivity (especially for thinner CIGSe [less than 2.0 μm]). It should be noted that, during manufacturing, the back-contact can be exposed to temperatures in the range of 500-600° C., or higher.

The most common back contacts for copper-indium-gallium-sulfur/selenium (CIGS), copper-zinc-tin-sulfur/selenium (CZTS), and CdTe PV devices contain molybdenum, either as part of a more complex back contact stack, or as the complete back contact. The main functionality of the back contact can be divided into 3 categories:

Electrical contact layer to the absorber,

Bulk current flow,

Good adhesion and minimal inter-diffusion between layers.

For example, a typical CIGSe PV device is made with a MoSe₂ contact layer and a Mo bulk current flow layer. CdTe devices typically use Al for bulk current flow. Various stacks have been disclosed to optimize cost and performance such as those disclosed in co-pending U.S. patent application Ser. No. 13/251,509, filed on Oct. 3, 2011, and U.S. patent application Ser. No. 13/283,291, filed on Oct. 27, 2011, each of which is herein incorporated by reference for all purposes.

Molybdenum tends to partially chalcogenize (react with Se and/or S) during the formation of the absorber layer. As a result, a layer of MoSe₂ or Mo(Se,S)₂ is formed between the Mo and the absorber layer. This contact layer results in reduced contact resistance (“quasi-ohmic contact”). The contact layer can also function as an electron reflector. Both effects can enhance the solar cell performance.

Unfortunately, the detailed composition and structure of the contact layer can change depending on the process conditions for absorber formation. Various studies have shown that the MoSe₂ thickness and orientation are of utmost importance for electrical performance and mechanical stability of the thin-film stack. For example, delamination of the contact layer from a CIGSe layer can occur if the MoSe₂ layer is too thick. The mass density and the electrical doping and impurity level of the MoSe₂ can impact the solar cell performance and its sensitivity to delamination during subsequent wet chemical bath deposition of the buffer layer. See, for example, Abou-Ras, et al., “Dependence of the MoSe₂ Formation on the Mo Orientation and the Na Concentration for Cu(In,Ga)Se₂ Thin-Film Solar Cells” Mater. Res. Soc. Symp. Proc, 865, F8.1.1-6, 2005; Eisenbarth, et al., “Interpretation of admittance, capacitance-voltage, and current-voltage signatures in Cu(In,Ga)Se₂ thin film solar cells,” J. Appl. Phys. 107, 034509, 2010; Glatzel, et al., “CuGaSe₂ solar cell cross section studied by Kelvin probe force microscopy in ultrahigh vacuum,” Appl. Phys. Let., 81, 2017-19, 2002; Klein, et al., “Interfaces in thin film solar cells,” Photovoltaic Specialists Conference, 2005. Conference Record of the Thirty-first IEEE, 205-10, 2005; Malmstrom, et al., “Enhanced back reflectance and quantum efficiency in Cu(In,Ga)Se₂ thin film solar cells with a ZrN back reflector,” Appl. Phys. Let., 85, 2634-36, 2004; Marron et al., “Lift-off process and rear-side characterization of CuGaSe2 chalcopyrite thin films and solar cells,” J. Appl. Phys. 97, 094915, 2005; Nishiwaki, et al., “MoSe₂ layer formation at Cu(In,Ga)Se₂/Mo Interfaces in High Efficiency Cu(In₁₋ₓGaₓ)Se₂ Solar Cells,” Jpn. J. Appl. Phys., 37, L71-73, 1998.

Therefore, there is a need for better control of the formation of a conformal, thin molybdenum chalcogenide layer.

### SUMMARY OF THE INVENTION

Solar cells and methods for forming solar cells are disclosed. In particular, methods for forming a back contact for a solar cell are disclosed. The methods comprise forming a first layer comprising a conductor, forming a second layer adjacent to the first layer, the second layer comprising between about 1 nm and about 25 nm of a metal chalcogenide, and forming a third layer operable as an absorber layer adjacent to the second layer.

The absorber layer can comprise a photoactive semiconductor layer. In some embodiments, the absorber layer comprises at least one Group I element, at least one Group III element, and at least one Group VI element. In some embodiments, the absorber layer comprises at least one Group II element, and at least one Group VI element. In some embodiments, the absorber layer further comprises at least one Group I element, and at least one Group IV element. In some embodiments, the absorber layer comprises a chalcogenide of copper-indium-gallium. In some embodiments, the absorber layer comprises a chalcogenide of copper-zinc-tin. In some embodiments, the absorber layer comprises CdTe.

In some embodiments, the conductor comprises a metal such as Mo, W or Ta. In some embodiments, the metal comprises Mo. In some embodiments, the chalcogenide comprises O, S, Se, or Te, or a combination thereof. In some embodiments, the chalcogenide comprises S or Se or a combination thereof.

In some embodiments, the second layer is deposited by atomic layer deposition. In some embodiments, the first layer is also deposited by atomic layer deposition. In some embodiments, the absorber layer is also deposited by atomic layer deposition.

In some embodiments, the order of deposition is first forming a conductor, then forming a metal chalcogenide, then forming an absorber layer, and the solar cell is in substrate configuration. In some embodiments, the order of deposition is first forming an absorber layer, then forming a metal chalcogenide, then forming a conductor, and the solar cell is in superstrate configuration.

In some embodiments, the methods further comprise designating site-isolated regions on the substrate, and varying one or more process parameters for forming the first layer, forming the second layer, or forming the third layer in a combinatorial manner among the site-isolated regions. The process parameters include process material amounts, reactant species, processing temperatures, processing times, ramp rates, cool-down rates, processing pressures, processing flow rates, processing powers, processing reagent compositions, the rates at which the reactions are quenched, atmospheres in which the processes are conducted, and order in which materials are deposited. In some embodiments, the methods further comprise characterizing each layer formed on the site-isolated regions, wherein characterizing each layer comprises measuring a structure or performance parameter for each of the plurality of site-isolated regions wherein the structure or performance parameter is one or more of crystallinity, grain size (distribution), lattice parameter, crystal orientation (distribution), matrix and minority composition, bandgap, bandgap grading, bulk bandgap, surface bandgap, efficiency, resistivity, carrier concentration, mobility, minority carrier lifetime, optical absorption coefficient, surface roughness, adhesion, thermal expansion coefficient, thickness, photoluminescence properties, surface photovoltage properties, haze, gloss, or specular reflection.

Solar cells are also disclosed herein. Solar cells comprise a substrate; a first layer comprising a conductor; a second layer adjacent to the first layer (i.e., in physical contact with the first layer), the second layer comprising between about 1 nm and about 25 nm of a metal chalcogenide; and a third layer adjacent to the second layer, the third layer operable as an optical absorber. In some embodiments, the absorber layer comprises at least one Group I element, at least one Group III element, and at least one Group VI element. In some embodiments, the absorber layer comprises at least one Group II element, and at least one Group VI element. In some embodiments, the absorber layer further comprises at least one Group I element, and at least one Group IV element. In some embodiments, the absorber layer comprises a chalcogenide of copper-indium-gallium. In some embodiments, the absorber layer comprises a chalcogenide of copper-zinc-tin. In some embodiments, the absorber layer comprises CdTe.

In some embodiments, the conductor comprises a metal such as Mo, W or Ta. In some embodiments, the metal comprises Mo. In some embodiments, the conductor comprises a metal nitride. In some embodiments, the chalcogenide comprises O, S, Se, or Te, or a combination thereof. In some embodiments, the chalcogenide comprises S or Se or a combination thereof.

In some embodiments, the solar cell is configured in substrate configuration. In some embodiments, the solar cell is configured in superstrate configuration.

### BRIEF DESCRIPTION OF THE DRAWINGS

FIG. 1 is a schematic diagram for implementing combinatorial processing and evaluation.

FIG. 2 is a schematic diagram for illustrating various process sequences using combinatorial processing and evaluation.

FIG. 3 illustrates a schematic diagram of a substrate TFPV stack with a back contact interface layer according to an embodiment described herein.

FIG. 4 illustrates a schematic diagram of a superstrate TFPV stack with a back contact interface layer according to an embodiment described herein.

### DETAILED DESCRIPTION

Before the present invention is described in detail, it is to be understood that unless otherwise indicated this invention is not limited to specific photovoltaic devices or specific layer stacks. It is also to be understood that the terminology used herein is for the purpose of describing particular embodiments only and is not intended to limit the scope of the present invention.

It must be noted that as used herein and in the claims, the singular forms “a,” “and” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. Where the term “about” is used in front of a numerical value, the value is deemed to be within ±10% of the numerical value.

As used herein, the term “Group I element” refers to Cu, Ag, or Au. As used herein, the term “Group II element” refers to Zn, Cd, or Hg. As used herein, the term “Group III element” refers to B, Al, Ga, In, or Tl. As used herein, the term “Group IV element” refers to C, Si, Ge, Sn, or Pb. As used herein, the term “Group VI element” refers to O, S, Se, Te, or Po. The skilled artisan will recognize these designations as columns of elements in the periodic table of the elements.

As used herein, the term “CIGS” refers to a TFPV comprising Cu, In, Ga, and one or more of S and Se. A CIGS absorber layer comprises elements from Group I, Group III, and Group VI. The atomic ratios can vary and may not be stoichiometric. For bandgap grading, each element can be partially substituted by an element from the same Group in the periodic table.

As used herein, the notation “Cu—In—Ga” and “Cu(In, Ga)” will be understood to include a material containing these elements in any ratio. The notation is extendable to other materials and other elemental combinations.

As used herein, the notation “CuₓIn_{y}Ga_{z}” will be understood to include a material containing these elements in a specific ratio given by x, y, and z (e.g. Cu₇₅Ga₂₅ contains 75 atomic % Cu and 25 atomic % Ga). The notation is extendable to other materials and other elemental combinations.

As used herein, the term “CZTS” refers to a TFPV comprising Cu, Zn, Sn, and one or more of S and Se. A CZTS absorber layer comprises elements from Group I, Group II, Group IV and Group VI. The atomic ratios can vary and may not be stoichiometric. The amount of Zn can be zero; hence the designation CZTS is taken herein to encompass “CTS” TFPVs containing Cu, Sn, and S and/or Se. For bandgap grading, each element can be partially substituted by an element from the same Group in the periodic table.

As used herein, “metal chalcogenide” or “chalcogenide” will be understood to represent the entire range of related compounds denoted by “MX” where M represents one or more metal elements and X represents one or more of the chalcogen elements (e.g., O, S, Se, or Te).

As used herein, the term “back contact layer” or “back contact” refers to a current-carrying layer on the side of the absorber layer facing away from the incoming light. In a substrate configuration TFPV device, the phrase “back contact” will be understood to be the primary current conductor layer situated between the substrate and the absorber layer. In a superstrate configuration TFPV device, the phrase “back contact” will be understood to be the primary current conductor layer, typically the top-most layer in the stack of layers on a substrate situated on the absorber layer. In some embodiments, the back contact layer can be textured so as to provide a textured surface for enhanced light absorption.

As used herein, “chalcogenize” and “chalcogenization” will be understood to represent the process by which one or more metals are converted to chalcogenide compounds by exposing the one or more metals to a chalcogen (e.g. O, S, Se, or Te) at elevated temperature (e.g. between 100° C. and 700° C.). Specifically, “selenization” will be understood to represent the process by which one or more metals are converted to selenide compounds by exposing the one or more metals to a Se source at elevated temperature (e.g. between 100° C. and 700° C.). Specifically, “sulfurization” will be understood to represent the process by which one or more metals are converted to sulfide compounds by exposing the one or more metals to a S source at elevated temperature (e.g. between 100° C. and 700° C.). In addition, “chalcogenize” or “chalcogenization” will be understood to represent the process by which a metal precursor is either partially or completely converted to the final multinary chalcogenide compound(s). Similarly, “chalcogenize” or “chalcogenization” will be understood to represent the process by which a precursor containing one or more chalcogenide materials with/without one or more elemental or alloy metals is converted to one or more dense, polycrystalline, desired multinary chalcogenide compound(s). It should be understood that the majority of the final film contains the desired multinary chalcogenide compound(s), yet a minority of the material might not be converted to the desired multinary chalcogenide compound(s).

As used herein, “substrate configuration” will be understood to describe TFPV stacks built sequentially on top of a substrate where the light is assumed to be incident upon the top of the TFPV stack. As used herein, an “n-substrate” configuration will be used to denote that the n-type layer (i.e. buffer layer) is closest to the incident light. The n-substrate configuration is the most common. As used herein, a “p-substrate” configuration will be used to denote that the p-type layer (i.e. absorber layer) is closest to the incident light.

As used herein, “superstrate configuration” will be understood to describe TFPV stacks built sequentially on top of a substrate where the light is assumed to be incident through the substrate onto the absorber. As used herein, an “n-superstrate” configuration will be used to denote that the n-type layer (i.e. buffer layer) is closest to the incident light. The n-substrate configuration is the most common. As used herein, a “p-superstrate” configuration will be used to denote that the p-type layer (i.e. absorber layer) is closest to the incident light.

As used herein, “substrate” will be understood to generally be one of float glass, low-iron glass, borosilicate glass, flexible glass, specialty glass for high temperature processing, stainless steel, carbon steel, aluminum, copper, titanium, molybdenum, polyimide, plastics, cladded metal foils, etc. Furthermore, the substrates may be processed in many configurations such as single substrate processing, multiple substrate batch processing, in-line continuous processing, roll-to-roll processing, etc. in all of the methods and examples described herein.

As used herein, “precursor layer,” “precursor material,” “metal precursor layer,” “metal precursor material,” etc. will be understood to be equivalent and be understood to refer to a metal, metal alloy, metal chalcogenide, etc. layer and/or material that is first deposited and will ultimately become the absorber layer of the TFPV device after full chalcogenization and/or further processing.

As used herein, “absorber layer,” “absorber material,” “optical absorber,” etc. will be understood to be equivalent and be understood to refer to a layer and/or material that is responsible for the charge generation in the TFPV device after full chalcogenization and/or further processing.

As used herein, the notations “Al:ZnO” and “ZnO:Al” will be understood to be equivalent and will describe a material wherein the base material is the metal oxide and the element separated by the colon, ‘:’, is considered a dopant. In this example, Al is a dopant in a base material of zinc oxide. The notation is extendable to other materials and other elemental combinations.

In some embodiments described below, a TFPV material stack has a simple planar structure. Those skilled in the art will appreciate that the description and teachings to follow can be readily applied to any simple or complex TFPV solar cell structure (e.g. a stack with conformal or non-conformal planar or non-planar layers optimized for photon management). The drawings are for illustrative purposes only and do not limit the application of the present invention.

In prior-art manufacturing methods, the metal chalcogenide layer is often both thicker and rougher than desired for optimum device performance, causing reduced specific contact resistivity and optical scattering at the boundary. The thickness and roughness are a byproduct of the chalcogenization of the absorber layer. Molybdenum tends to partially chalcogenize (react with Se and/or S) during the formation of the absorber layer. As a result, a layer of MoSe₂ or Mo(Se,S)₂ is formed between the Mo and the absorber layer. Unfortunately, the detailed composition and structure of the contact layer can change depending on the process conditions for absorber formation. Delamination of the contact layer from a CIGSe layer can occur if the MoSe₂ layer is too thick. The mass density and the electrical doping and impurity level of the MoSe₂ can impact the solar cell performance and its sensitivity to delamination during subsequent wet chemical bath deposition of the buffer layer.

The present Specification discloses novel solar cells and methods of forming the solar cells. The novel methods disclosed herein provide precise control over the thickness and composition of the back contact interface layer to prevent delamination and provide precise control over contact resistance, surface roughness and resulting optical scattering at the boundary.

Solar cells comprise a substrate; a first layer, the first layer comprising a conductor; a second layer adjacent to the first layer (i.e., in physical contact with the first layer), the second layer comprising between about 1 nm and about 25 nm of a metal chalcogenide; and a third layer adjacent to the second layer, the third layer comprising an optical absorber. In some embodiments, the absorber layer comprises a chalcogenide of copper-indium-gallium. In some embodiments, the absorber layer comprises a chalcogenide of copper-tin. In some embodiments, the absorber layer comprises a chalcogenide of copper-zinc-tin. In some embodiments, the absorber layer comprises CdTe. In some embodiments, the conductor comprises a metal such as Mo, W or Ta. In some embodiments, the metal comprises Mo. In some embodiments, the conductor comprises a metal nitride. In some embodiments, the chalcogenide comprises S or Se or a combination thereof.

The methods comprise forming a first layer comprising a conductor, forming a second layer adjacent to the first layer, the second layer comprising between about 1 nm and about 25 nm of a metal chalcogenide, and forming a third layer operable as an absorber layer adjacent to the second layer. The absorber layer can comprise a photoactive semiconductor layer. In some embodiments, the absorber layer comprises a chalcogenide of copper-indium-gallium. In some embodiments, the absorber layer comprises a chalcogenide of copper-tin. In some embodiments, the absorber layer comprises a chalcogenide of copper-zinc-tin. In some embodiments, the absorber layer comprises CdTe. In some embodiments, the conductor comprises a metal such as Mo, W or Ta. In some embodiments, the metal comprises Mo. In some embodiments, the chalcogenide comprises S or Se or a combination thereof.

In some embodiments, the second layer is deposited by atomic layer deposition. In some embodiments, the first layer is also deposited by atomic layer deposition. In some embodiments, the absorber layer is also deposited by atomic layer deposition. The methods comprise independently controlling the formation of a metal chalcogenide (e.g., MoSe₂ or MoS₂) layer at the boundary between the back contact layer and the absorber layer in CIGS, CZTS, and CdTe solar cells.

For a substrate TFPV, the MoSe₂ layer is formed incidental to the selenization of the absorber layer. It is necessary to optimize both the Mo deposition and absorber selenization conditions, which can limit the optimization of the back-contact-to-absorber interface, and even the optimization of the absorber itself. In some embodiments, this limitation can be overcome by separately depositing a thin MoSe₂ layer which allows for control over the orientation and thickness of the MoSe₂ layer.

The order of layer forming steps to produce a substrate TFPV are reversed for a superstrate TFPV, and the challenges for formation of the back contact layer vary accordingly. For a superstrate TFPV, the absorber layer is deposited before the back contact and selenization can be completed before the back contact layer is deposited. The MoSe₂ layer is not needed to function as a barrier layer against Se migration, but it is still valuable to reduce contact resistance. Accordingly, the ability to precisely control the thickness of a MoSe₂ layer can be especially important for superstrate TFPVs.

In some embodiments, a very thin Mo chalcogenide layer (the second layer described above) is formed before the absorber layer is deposited using controlled growth methods such as atomic layer deposition (ALD) or reactive sputtering. By forming the Mo chalcogenide layer separately, it is possible to control the thickness and roughness of the layer to better optimize device performance. The Mo chalcogenide layer can further serve as a diffusion barrier to prevent further chalcogenization of the back contact metal during the chalcogenization of the absorber layer.

In recent years, ALD has moved from wafer-only semiconductor applications in batch furnaces to other and larger substrates, both in batch units and in-line units. Several companies (for example, Smit Ovens, B.V., Solaytec B.V., Beneq, ASM International, N.V.) are offering new atmospheric-pressure, in-line ALD units which offer increased versatility, reduced cost, and increased throughput. Large in-line units that can process volume solar cell production are now feasible. ALD is known for its conformal deposition capability and dense layers, the latter being especially suitable for forming diffusion barrier layers. In some embodiments, to form a molybdenum chalcogenide layer by ALD, Mo precursors are selected from MoO₃ powder, Mo(CO)₆, and MoF₆. Chalcogen precursors can be selected from H₂Se, H₂S, Se powder or vapor, and S powder or vapor. Other metals can be used such as W or Ta. Other chalcogens such as O or Te can be used.

In some embodiments, a first layer comprising a metal for bulk-current carrying, the metal comprising, for example, Mo or Al is deposited on a suitable substrate. (Typical substrates for solar cells are glass, but other substrate materials are also possible.) A second layer having a controlled thickness of molybdenum chalcogenide (MoSe₂, MoS₂, or Mo(S,Se)₂) is then formed on the first layer. The controlled thickness can be between about 1 nm and about 25 nm. ALD can be used to deposit the second layer with high precision, although other deposition methods are also possible. Reactive ion sputtering (physical vapor deposition or PVD) can be used as can chemical vapor deposition (CVD), electroplating, and solution deposition from a molecularly dissolved species. The deposition method is not critical as long as sufficient control can be achieved over the thickness of the second layer. An absorber layer such as CIGS, CZTS, or CdTe can then be formed on the second layer. In some embodiments, the absorber layer is formed by first depositing metal precursors, then chalcogenizing by heating the precursors in a chalcogen-containing atmosphere as described in co-pending U.S. patent application Ser. No. 13/283,225, filed on Oct. 27, 2011, and U.S. patent application Ser. No. 13/461,495, filed on May 1, 2012, each of which is herein incorporated by reference for all purposes. The controlled thickness second layer can function as a barrier that prevents further chalcogenization of the metal layer during the chalcogenization of the absorber.

In some embodiments HPC methods are applied to the task of optimizing the performance of a PV device including a controlled-thickness metal chalcogenide layer. The process parameters for the deposition of the controlled-thickness metal chalcogenide layer can be varied in a combinatorial manner among site-isolated regions on a substrate. Exemplary process parameters that can be varied include precursor selection, as well as process times, temperatures, and pressures. These process parameters can be varied either alone or in combination with process parameters for forming other device layers including the bulk-current-carrying layer, the absorber, the buffer layer, and the front contact layer.

In some embodiments, the methods of forming solar cells further comprise designating site-isolated regions on the substrate, and varying one or more process parameters for depositing the first layer, depositing the second layer, or forming the absorber layer in a combinatorial manner among the site-isolated regions. The process parameters include process material amounts, reactant species, processing temperatures, processing times, ramp rates, cool-down rates, processing pressures, processing flow rates, processing powers, processing reagent compositions, the rates at which the reactions are quenched, atmospheres in which the processes are conducted, and order in which materials are deposited. In some embodiments, the methods further comprise characterizing each layer formed on the site-isolated regions, wherein characterizing each layer comprises measuring a structure or performance parameter for each of the plurality of site-isolated regions wherein the structure or performance parameter is one or more of crystallinity, grain size (distribution), lattice parameter, crystal orientation (distribution), matrix and minority composition, bandgap, bandgap grading, bulk bandgap, surface bandgap, efficiency, resistivity, carrier concentration, mobility, minority carrier lifetime, optical absorption coefficient, surface roughness, adhesion, thermal expansion coefficient, thickness, photoluminescence properties, surface photovoltage properties, haze, gloss, or specular reflection.

The efficiency of thin-film photovoltaic (TFPV) devices depends on many properties of the absorber layer and the buffer layer such as crystallinity, grain size, composition uniformity, density, defect concentration, doping level, surface roughness, etc. The manufacture of TFPV devices entails the integration and sequencing of many unit processing steps. As an example, TFPV manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as TFPV devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching, texturing, polishing, cleaning, etc. HPC processing techniques have also been successfully adapted to deposition processes such as sputtering, atomic layer deposition (ALD), and chemical vapor deposition (CVD).

HPC processing techniques have been adapted to the development and investigation of absorber layers and buffer layers for TFPV solar cells as described in U.S. application Ser. No. 13/236,430 filed on Sep. 19, 2011, entitled “COMBINATORIAL METHODS FOR DEVELOPING SUPERSTRATE THIN FILM SOLAR CELLS” and incorporated herein by reference. However, HPC processing techniques have not been successfully adapted to the development of contact structures for TFPV devices. Generally, there are two basic configurations for TFPV devices. The first configuration is known as a “substrate” configuration. In this configuration, the contact that is formed on or near the substrate is called the back contact. In this configuration, the light is incident on the TFPV device from the top of the material stack (i.e. the side opposite the substrate). CIGS TFPV devices are most commonly manufactured in this configuration. The second configuration is known as a “superstrate” configuration. In this configuration, the contact that is formed on or near the substrate is called the front contact. In this configuration, the light is incident on the TFPV device through the substrate. CdTe, and a-Si, TFPV devices are most commonly manufactured in this configuration. In both configurations, light trapping schemes may be implemented in the contact layer that is formed on or near the substrate. Additionally, other efficiency or durability improvements can be implemented in the contact layer that is formed farthest away from the substrate.

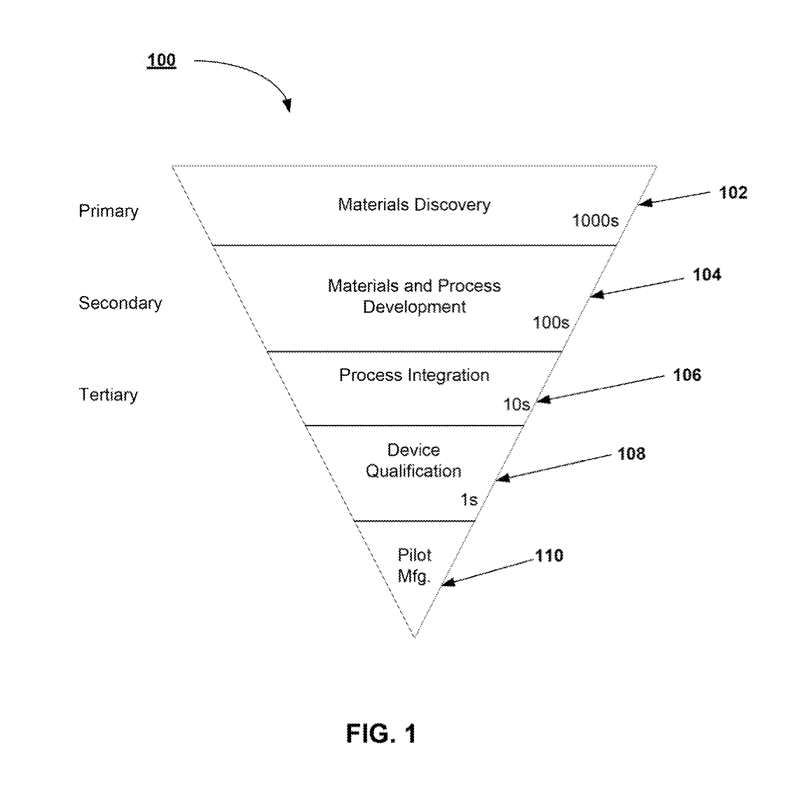

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of TFPV manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a TFPV device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a TFPV device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the TFPV device. For example, such structures may include, but would not be limited to, contact layers, buffer layers, absorber layers, or any other series of layers or unit processes that create an intermediate structure found on TFPV devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

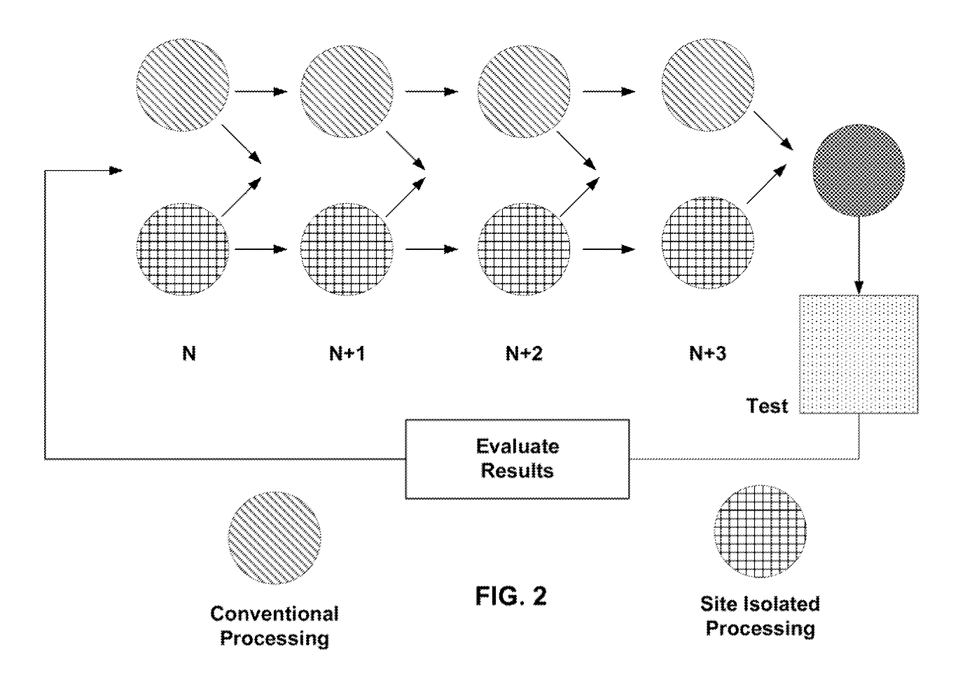

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. The combinatorial processing may employ uniform processing of site isolated regions or may employ gradient techniques. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in TFPV manufacturing may be varied.

As mentioned above, within a region, the process conditions are substantially uniform. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. However, in some embodiments, the processing may result in a gradient within the regions. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Process parameters for forming each layer on the plurality of SIRs are varied in a combinatorial manner to prepare unique variations for testing optical absorber compositions. The methods for forming layers can vary as described above, and include dry processing methods and wet processing methods, varying process parameters appropriate to each method.

The process parameters can include process material amounts, reactant species, processing temperatures, processing times, ramp rates, cool-down rates, processing pressures, processing flow rates, processing powers, processing reagent compositions, the rates at which the reactions are quenched, atmospheres in which the processes are conducted, and order in which materials are deposited. In some embodiments, the relative amounts of the two or more elements and the at least one grading element can be varied in a combinatorial manner among the plurality of discrete SIRs designated on the substrate. In some embodiments, the characterizing each semiconductor layer comprises measuring a structure or performance parameter for each of the plurality of site-isolated regions. In some embodiments, the structure or performance parameter is one or more of crystallinity, grain size (distribution), lattice parameter, crystal orientation (distribution), matrix and minority composition, bandgap, bandgap grading, bulk bandgap, surface bandgap, efficiency, resistivity, carrier concentration, mobility, minority carrier lifetime, optical absorption coefficient, surface roughness, adhesion, thermal expansion coefficient, thickness, photoluminescence properties, surface photovoltage properties, haze, gloss, specular reflection, etc.

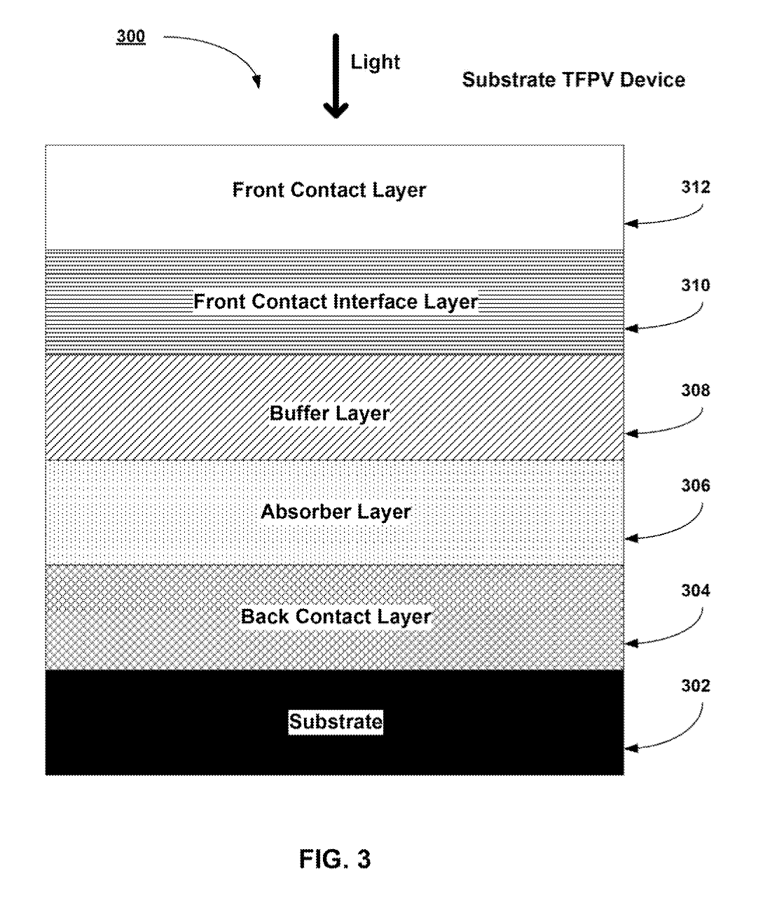

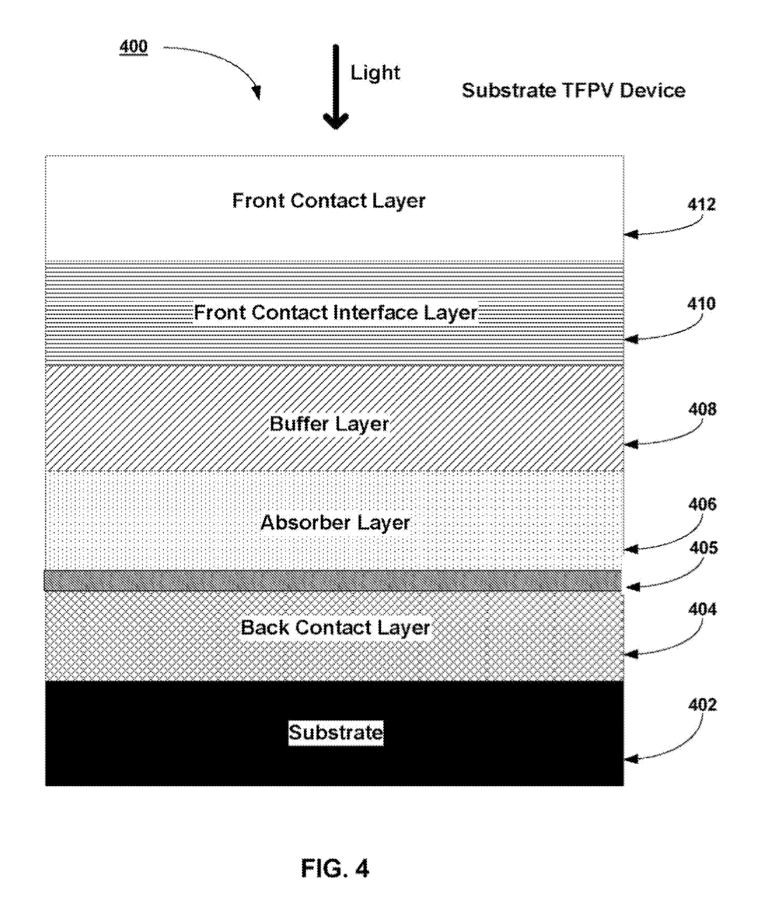

In FIGS. 3 and 4 below, a TFPV material stack is illustrated using a simple planar structure. Those skilled in the art will appreciate that the description and teachings to follow can be readily applied to any simple or complex TFPV solar cell morphology. The drawings are not to scale and are for illustrative purposes only and do not limit the application of the present invention.

FIG. 3 illustrates a schematic diagram of a TFPV device stack in the substrate configuration consistent with some embodiments of the present invention. The convention will be used wherein light is assumed to be incident upon the top of the material stack in the substrate configuration as illustrated. This generic diagram would be typical of a CTS or CZTS or CIGS or CdTe TFPV device. Substrate 302 is shown as the bottommost supporting layer. Examples of suitable substrates comprise float glass, low-iron glass, borosilicate glass, flexible glass, specialty glass for high temperature processing, stainless steel, carbon steel, aluminum, copper, titanium, molybdenum, polyimide, plastics, cladded metal foils, etc. Furthermore, the substrates may be processed in many configurations such as single substrate processing, multiple substrate batch processing, in-line continuous processing, roll-to-roll processing, etc.

Optionally, a diffusion barrier and/or adhesion-promotion layer (not shown) may be formed between the substrate and the back contact layer. When implemented, the diffusion barrier layer stops the diffusion of impurities from the substrate into the back contact layer, or alternatively, stops the diffusion and reaction of the back contact material with the substrate. Examples of absorber layers, diffusion barrier layers, and/or adhesion-promotion layers are described in co-pending U.S. patent application Ser. No. 13/727,986, filed on Dec. 27, 2012, U.S. patent application Ser. No. 14/034,226, filed on Sep. 23, 2013, U.S. patent application Ser. No. 14/105,797, filed on Dec. 13, 2013, each of which is herein incorporated by reference for all purposes.

A first layer comprising a conductor (a back contact layer), 304, is formed on substrate 302. As used herein, the phrase “back contact” will be understood to be the primary current conductor layer situated between the substrate and the absorber layer in a substrate configuration TFPV device. The back contact layer 304 may be formed by any number of deposition technologies. In some embodiments, the back contact layer material is Mo for CIGS or CZTS TFPV devices. CdTe TFPVs are commonly built with Mo contacting the absorber followed by a current carrying layer of Al and a thin layer of Cr for solderability. In some embodiments, the back contact comprises other metals or metal nitrides. Examples of suitable deposition technologies comprise physical vapor deposition (PVD) (e.g. sputtering), evaporation, chemical vapor deposition (CVD), atomic layer deposition (ALD), plating, printing, wet coating, etc. The thickness of the back contact layer is typically between about 0.3 μm and about 1.0 μm. The back contact layer has a number of requirements such as high conductivity, good ohmic contact to the absorber layer, ease of bonding to tabs for external connectivity, ease of scribing or other removal, good thermo-mechanical stability, and chemical resistance during subsequent processing, among others.

A second layer comprising a metal chalcogenide 305 is formed on top of the back contact layer. The second layer is a quasi-ohmic contact layer which imparts reduced contact resistance with the absorber layer, and can potentially act as an electron reflector, enhancing solar cell performance. In some embodiments the second layer 305 is a very thin molybdenum chalcogenide layer (between about 1 nm and about 25 nm thick) formed before the absorber layer. The second layer is deposited using controlled growth methods such as atomic layer deposition (ALD) or reactive sputtering. By forming the Mo chalcogenide layer separately, it is possible to control the thickness and roughness of the layer to better optimize device performance. The Mo chalcogenide layer can further serve as a diffusion barrier to prevent further chalcogenization of the back contact metal during the chalcogenization of the absorber layer.

A third layer comprising a p-type absorber layer 306, of CIGS, CTS, CZTS, or CdTe is then deposited on top of the back contact layer. The absorber layer may be formed, partially or completely, using a variety of techniques such as PVD (sputtering), co-evaporation, in-line evaporation, plating, printing or spraying of inks, screen printing, inkjet printing, slot die coating, gravure printing, wet chemical depositions, CVD, etc. In some embodiments, the absorber layer is deposited as a precursor layer that undergoes a selenization process after formation to convert the precursor into a chalcogenide. In some embodiments, the precursor and/or absorber layer undergoes a sulfurization or selenization process after formation to convert the precursor to a chalcogenide. The sulfurization or selenization process involves the exposure of the precursor and/or absorber layer to H₂Se, H₂S, Se vapor, S vapor, or diethylselenide (DESe) at temperatures most typically between about 300° C. and 700° C. It should be noted that the precursor might already contain a chalcogen source (e.g., S), either as a separate layer, or incorporated into the bulk of the precursor layer. The precursor film can be a stack of layers, or one layer. The precursor layer can be dense, or porous. For example, the precursor film typically contains Cu, Zn, and Sn to form CZTS, or Cu and Sn to form CTS. The thickness of the absorber layer is typically between about 1.0 μm and about 3.0 μm. The performance of the absorber layer is sensitive to materials properties such as crystallinity, grain size, surface roughness, composition, defect concentration, etc. as well as processing parameters such as temperature, deposition rate, thermal treatments, etc.

An n-type buffer layer, 308, is then deposited on top of the absorber layer. Examples of suitable n-type buffer layers comprise CdS, ZnS, In₂S₃, In₂(S,Se)₃, (Cd,Zn)S, ZnO, Zn(O,S), (Zn,Mg)O, etc. CdS is the material most often used as the n-type buffer layer in CZTS TFPV devices. The buffer layer may be deposited using chemical bath deposition (CBD), chemical surface deposition (CSD), PVD (sputtering), printing, plating, ALD, Ion-Layer-Gas-Reaction (ILGAR), ultrasonic spraying, or evaporation. The thickness of the buffer layer is typically between about 30 nm and about 100 nm. The performance of the buffer layer is sensitive to materials properties such as crystallinity, grain size, surface roughness, composition, defect concentration, etc. as well as processing parameters such as temperature, deposition rate, thermal treatments, etc.

Optionally, a front contact interface layer 310 is formed on top of the buffer layer. The front contact interface layer can be an intrinsic ZnO (iZnO) layer, which is a high resistivity material and forms part of the transparent conductive oxide (TCO) stack that serves as part of the front contact structure. Other resistive metal oxides like SnO₂, resistive ZnO:Al, resistive In—Ga—Zn—O, etc. might be used instead of i-ZnO. The TCO stack is formed from transparent conductive metal oxide materials and collects charge across the face of the TFPV solar cell and conducts the charge to tabs used to connect the solar cell to external loads. The iZnO layer makes the TFPV solar cell less sensitive to lateral non-uniformities caused by differences in composition or defect concentration in the absorber and/or buffer layers. The iZnO layer is typically between about 0 nm and 150 nm in thickness. The iZnO layer is typically formed using a (reactive) PVD (sputtering) technique or CVD technique, but can be deposited by plating or printing as well.

A front contact layer 312 is formed on top of the iZnO layer. The front contact layer is a low resistivity top TCO layer such as, but not limited to, Al:ZnO (AZO), (In,Sn)O (ITO), (In,Zn)O, B:ZnO, Ga:ZnO, F:ZnO, F:SnO₂, etc. The top TCO layer is typically between about 0.25 μm and 1.0 μm in thickness. The top TCO layer is typically formed using a (reactive) PVD (sputtering) technique or CVD technique. Optionally, the transparent top electrode can be printed or wet-coated from (silver) nano-wires, carbon nanotubes, and the like.

FIG. 4 illustrates a schematic diagram of a TFPV device, 400, consistent with some embodiments of the present invention. The TFPV device illustrated in FIG. 4 is shown in a superstrate configuration wherein a transparent substrate faces the incident sunlight. The convention will be used wherein light is assumed to be incident upon the substrate and material stack as illustrated. As used herein, this configuration will be labeled an “n-superstrate” configuration to denote that the n-type layer (i.e. buffer layer) is closest to the incident light. The formation of the TFPV device will be described starting with the substrate. Examples of suitable substrates comprise float glass, low-iron glass, borosilicate glass, flexible glass, specialty glass for high temperature processing, polyimide, high-temperature plastics, etc. Furthermore, the substrates may be processed in many configurations such as single substrate processing, multiple substrate batch processing, in-line continuous processing, roll-to-roll processing, etc.

A low resistivity bottom TCO front contact layer, 404, (examples include Al:ZnO (AZO), (In,Sn)O (ITO), (In,Zn)O, B:ZnO, Ga:ZnO, F:ZnO, F:SnO₂, etc.) is formed on top of the substrate, 402. As used herein, the phrase “front contact” will be understood to be the primary current conductor layer situated between the substrate and the buffer layer in a superstrate configuration TFPV device. The bottom TCO layer is typically between about 0.3 μm and 2.0 μm in thickness. The bottom TCO layer is typically formed using a reactive PVD (sputtering) technique or CVD technique.

Optionally, a diffusion barrier and/or adhesion-promotion layer (not shown) may be formed between the substrate, 402, and the front contact layer, 404. When implemented, the diffusion barrier layer stops the diffusion of impurities from the substrate into the TCO, or alternatively, stops the diffusion and reaction of the TCO material and above layers with the substrate. It should be understood that the diffusion barrier layer composition and thickness are optimized for optical transparency as necessary for the superstrate configuration. The diffusion barrier layer may be formed from any well known technique such as sputtering, ALD, CVD, evaporation, wet methods such as printing or spraying of inks, screen printing, inkjet printing, slot die coating, gravure printing, wet chemical depositions, or from sol-gel methods, such as the coating, drying, and firing of polysilazanes.

An intrinsic iZnO layer, 406, is then formed on top of the TCO layer. The iZnO layer is a high resistivity material and forms part of the transparent conductive oxide (TCO) stack that serves as part of the front contact structure. Other resistive metal oxides like SnO₂, resistive ZnO:Al, resistive In—Ga—Zn—O, etc. might be used instead of i-ZnO. The iZnO layer makes the TFPV device less sensitive to lateral non-uniformities caused by differences in composition or defect concentration in the absorber and/or buffer layers. The iZnO layer is typically between about 0 nm and 150 nm in thickness. The iZnO layer is typically formed using a reactive PVD (sputtering) technique or CVD technique.

An n-type buffer layer, 408, is then deposited on top of the iZnO layer, 406. Examples of suitable n-type buffer layers comprise CdS, ZnS, In₂S₃, In₂(S,Se)₃, (Cd,Zn)S, ZnO, Zn(O,S), (Zn,Mg)O, etc. CdS is the material most often used as the n-type buffer layer in TFPV devices. The buffer layer may be deposited using chemical bath deposition (CBD), chemical surface deposition (CSD), PVD (sputtering), printing, plating, ALD, Ion-Layer-Gas-Reaction (ILGAR), ultrasonic spraying, or evaporation. The thickness of the buffer layer is typically between about 30 nm and about 100 nm. The performance of the buffer layer is sensitive to materials properties such as crystallinity, grain size, surface roughness, composition, defect concentration, etc. as well as processing parameters such as temperature, deposition rate, thermal treatments, etc.

A p-type absorber layer, 410, is then deposited on top of the buffer layer. The absorber layer may be formed, partially or completely, using a variety of techniques such as PVD (sputtering), co-evaporation, in-line evaporation, plating, printing or spraying of inks, screen printing, inkjet printing, slot die coating, gravure printing, wet chemical depositions, CVD, etc. In some embodiments, the absorber layer is deposited as a precursor layer that undergoes a selenization process after formation to convert the precursor into a chalcogenide. The selenization process involves the exposure of the precursor and/or absorber layer to H₂Se, H₂S, Se vapor, S vapor, or diethylselenide (DESe) at temperatures most typically between about 300° C. and 700° C. It should be noted that the precursor might already contain a chalcogen source (e.g. Se), either as a separate layer, or incorporated into the bulk of the precursor layer. The precursor film can be a stack of layers, or one layer. The precursor layer can be dense, or porous. The thickness of the absorber layer is typically between about 1.0 μm and about 3.0 μm. The performance of the absorber layer is sensitive to materials properties such as crystallinity, grain size, surface roughness, composition, defect concentration, etc. as well as processing parameters such as temperature, deposition rate, thermal treatments, etc.

An interface layer 411 is formed on top of the absorber layer. The interface layer is a quasi-ohmic contact layer which imparts reduced contact resistance with the absorber layer, and can potentially act as an electron reflector, enhancing solar cell performance. In some embodiments the interface layer 411 is a very thin molybdenum chalcogenide layer (between about 1 nm and about 25 nm thick) formed after the absorber layer. The interface layer is deposited using controlled growth methods such as atomic layer deposition (ALD) or reactive sputtering. By forming the Mo chalcogenide layer separately, it is possible to control the thickness and roughness of the layer to better optimize device performance. The Mo chalcogenide layer can further serve as a diffusion barrier to prevent further chalcogenization of the back contact metal during the chalcogenization of the absorber layer.

A back contact layer, 412, is formed on the interface layer, 411. An example of a common back contact layer material is Mo for CIGS or CZTS TFPV devices. The back contact layer may be formed by any number of deposition technologies. Examples of suitable deposition technologies comprise PVD (sputtering), evaporation, chemical vapor deposition (CVD), atomic layer deposition (ALD), plating, etc. The thickness of the back contact layer is typically between about 0.3 μm and about 1.0 μm. The back contact layer has a number of requirements such as high conductivity, good ohmic contact to the absorber layer, ease of bonding to tabs for external connectivity, ease of scribing or other removal, good thermo-mechanical stability, and chemical resistance during subsequent processing, among others. Other types of TFPV devices use different materials for the back contact. As an example, Cu-based materials such as Cu/Au, Cu/graphite, Cu/Mo, Cu:ZnTe/Mo, etc. can be used for CdTe TFPV devices.

It will be further understood that, while exemplary methods have been described for a PV device in substrate configuration, equivalent methods can be applied to PV devices formed in superstrate configuration.

It will be understood that the descriptions of one or more embodiments of the present invention do not limit the various alternative, modified and equivalent embodiments which may be included within the spirit and scope of the present invention as defined by the appended claims. Furthermore, in the detailed description above, numerous specific details are set forth to provide an understanding of various embodiments of the present invention. However, one or more embodiments of the present invention may be practiced without these specific details. In other instances, well known methods, procedures, and components have not been described in detail so as not to unnecessarily obscure aspects of the present embodiments.

What is claimed is:

1. A method of forming a back contact for a solar cell, the method comprising
forming a first layer comprising a conductor,
forming a second layer adjacent to the first layer, the second layer comprising a metal chalcogenide, the second layer having a thickness between about 1 nm and about 25 nm,
forming a third layer adjacent to the second layer, wherein the third layer is operable as an absorber layer.

2. The method of claim 1, wherein the absorber layer comprises at least one Group I element, at least one Group III element, and at least one Group VI element.

3. The method of claim 1, wherein the absorber layer comprises at least one Group II element, and at least one Group VI element.

4. The method of claim 3, wherein the absorber layer further comprises at least one Group I element, and at least one Group IV element.

5. The method of claim 1, wherein the conductor comprises Mo, W or Ta.

6. The method of claim 5, wherein the conductor comprises Mo.

7. The method of claim 1, wherein the second layer is deposited by atomic layer deposition.

8. The method of claim 1, wherein the first layer is deposited by atomic layer deposition.

9. The method of claim 1, wherein the order of deposition is first forming a conductor, then forming a metal chalcogenide, then forming an absorber layer, and the solar cell is in substrate configuration.

10. The method of claim 1, wherein the order of deposition is first forming an absorber layer, then forming a metal chalcogenide, then forming a conductor, and the solar cell is in superstrate configuration.

11. A method of forming a contact for a solar cell, the method comprising
designating a plurality of site-isolated regions (SIR) on a substrate,
forming a first layer comprising a conductor within each SIR,
forming a second layer adjacent to the first layer within each SIR, the second layer comprising a metal chalcogenide, the second layer having a thickness between about 1 nm and about 25 nm;
forming a third layer adjacent to the second layer within each SIR, wherein the third layer is operable as an absorber layer,
varying one or more process parameters for forming the first layer, forming the second layer, or forming the third layer in a combinatorial manner among the plurality of site-isolated regions.

12. A solar cell comprising
a substrate;
a first layer above the substrate, the first layer comprising a conductor;
a second layer adjacent to the first layer, the second layer comprising a metal chalcogenide, the second layer having a thickness between about 1 nm and about 25 nm of; and
a third layer adjacent to the second layer, the third layer operable as an optical absorber.

13. The solar cell of claim 12, wherein the absorber layer comprises at least one Group I element, at least one Group III element, and at least one Group VI element.

14. The solar cell of claim 12, wherein the absorber layer comprises at least one Group II element, and at least one Group VI element.

15. The solar cell of claim 14, wherein the absorber layer further comprises at least one Group I element, and at least one Group IV element.

16. The solar cell of claim 12, wherein the conductor comprises Mo, W or Ta.

17. The solar cell of claim 16, wherein the conductor comprises Mo.

18. The solar cell of claim 12, wherein the conductor comprises a metal nitride.

19. The solar cell of claim 12, wherein the layers are arranged in substrate configuration.

20. The solar cell of claim 12, wherein the layers are arranged in superstrate configuration.
